(19) United States
(12) Patent Application Publication
(10) Pub. No.: US 2007/0229191 A1
(43) Pub. Date: Oct. 4, 2007

(54) SURFACE ACOUSTIC WAVE ELEMENT AND SURFACE ACOUSTIC WAVE DEVICE COMPRISING THE ELEMENT

(75) Inventors: Masahiro Yamaki, Tokyo (JP); Yoshikazu Kihara, Tokyo (JP); Eiko Wakata, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK CORPORATION, Tokyo (JP)

(21) Appl. No.: 11/681,563

(22) Filed: Mar. 2, 2007

(30) Foreign Application Priority Data
Mar. 31, 2006 (JP) 2006-096517

(51) Int. Cl. H03H 9/64

(52) U.S. Cl. 333/193

(57) ABSTRACT

A surface acoustic wave element comprises a first surface acoustic wave element unit formed on a surface of a piezo-electric substrate, and a second surface acoustic wave element unit formed on the surface of said piezo-electric substrate adjacent to said first surface acoustic wave element unit. Each of said first surface acoustic wave element unit and said second surface acoustic wave element unit includes a signal input terminal, a signal output terminal, a ground terminal, a signal path for coupling said signal input terminal to the signal output terminal, series arm resonators connected in series on said signal path, a branch line branched from said signal path to said ground terminal, and parallel arm resonators connected on said branch line. The signal path of at least one of the first surface acoustic wave element unit and second surface acoustic wave element unit is extended outside of the center line of said surface acoustic wave element unit.

### BACKGROUND OF THE INVENTION

The present invention relates to a surface acoustic wave element, and a surface acoustic wave device which comprises the element, and more particularly, to techniques for preventing coupling (electromagnetic coupling) that can occur between respective ones of a plurality of surface acoustic wave elements which are contained in a surface acoustic wave device.

Surface acoustic wave (hereinafter called “SAW”) devices, which utilize surface acoustic waves generated by piezo-electric effects, are widely used as signal processing devices such as filters, duplexers and the like in a variety of electronic devices represented by mobile communication devices because of their small size, a light weight, and excellency in reliability. Such SAW devices are generally fabricated by mounting chip-shaped SAW elements, each having a plurality of resonators disposed on a piezo-electric substrate, on a base substrate made of resin or ceramics, and hermetically packaging the SAW elements.

Each resonator in the SAW element comprises an interdigital transducer (hereinafter called “IDT”) formed on the surface of the piezo-electric substrate. Each resonator is electrically connected through a conductor pattern formed likewise on the piezo-electric substrate to form a transmission filter and a reception filter having different particular frequency bands, respectively, when it is intended to form part of a duplexer, by way of example. In recent years, the mounting of SAW elements on the base substrate has been gradually changed from a wire bonding (WB) method to a flip-chip bonding (FCB) method which is more advantageous for a lower profile.

JP-A-2003-101381 and JP-A-11-145772, for example, disclose techniques for preventing coupling in such a SAW device, more specifically between a plurality of SAW elements disposed within the SAW device. Specifically, for reducing the coupling between SAW elements, input electrodes and output electrodes of SAW elements are placed along edges or corners different from one another on a piezo-electric substrate in JP-A-2003-101381, while a plurality of ground lead conductors are disposed in a surface-mount package in JP-A-11-145772.

### SUMMARY OF THE INVENTION

In recent years, electronic devices such as mobile communication devices and the like have been significantly reduced in size, so that SAW devices for use in these devices are also required to provide a comparably larger reduction in size and higher performance (improved characteristics).

However, a larger reduction in size of a device causes SAW elements to be correspondingly closer to one another, resulting in lower isolation characteristics among the elements. For example, when a duplexer is fabricated as mentioned above, both transmission and reception filters can be coupled to each other to give rise to deteriorated attenuation characteristics in a rejection band. Particularly, with the employment of a SAW device structure that involves forming a plurality of SAW elements on a single piezo-electric substrate, which is advantageous in reduction in size and simplification of manufacturing steps, elements tend to be located closer and therefore more prone to coupling, as compared with a conventional SAW device structure which involves fabricating respective SAW elements as individual chips, so that a need exists for the provision of techniques for preventing the coupling in a more satisfactory manner.

It is therefore an object of the present invention to improve electric characteristics of a SAW device which comprises a plurality of SAW elements, and more particularly, to further reduce the coupling which can occur between a plurality of SAW elements.

To achieve the above object and solve the problem a SAW (surface acoustic wave) element of the present invention comprises a first SAW element unit formed on a surface of a piezo-electric substrate, and a second SAW element unit formed on the surface of the piezo-electric substrate adjacent to the first SAW element unit, wherein each of the first SAW element unit and the second SAW element unit includes an input terminal for inputting a signal therethrough, an output terminal for outputting a signal therethrough, a ground terminal connected to a ground, a signal path for coupling the input terminal to the output terminal, one or more series arm resonators connected in series on the signal path, a branch line branched from the signal path to the ground terminal, and one or more parallel arm resonators connected on the branch line, where the signal path of at least one of the first SAW element unit and second SAW element unit is extended outside of a center line of the SAW element.

The inventors made investigations in order to further improve electric characteristics of SAW devices, and found that in the state-of-art SAW devices, no particular attention had been paid to the routing of wires (conductive paths) which interconnected respective resonators on a piezo-electric substrate and there was a room for further improvements in this respect.

Specifically, FIG. 12 is a top plan view schematically illustrating an example of a conventional SAW element (SAW element for a duplexer). This SAW element comprises two SAW element units 1, 2, i.e., a transmission filter 1 and a reception filter 2 in close proximity to each other on a single piezo-electric substrate 5, where each SAW element unit 1, 2 is a ladder SAW filter element which comprises a plurality of series arm resonators S11, S12, S13, S21, S22 connected in series on a signal path L1 which connects a signal input terminal T1, R1 to a signal output terminal T2, R2; and a plurality of parallel arm resonators P11, P12, P21, P22, P23 connected to branch lines L2 branched from the signal path L1 and reach respective ground terminals G.

Here, in this SAW element structure, part of the signal path L1 (a portion of the signal path near the last series arm resonator S13 as viewed from the signal input terminal T1) of the transmission filter 1, and part of the signal path L1 (a portion of the signal path between the two series arm resonators S21, S22) of the reception filter 2 are close to each other (see arrow A in FIG. 12), so that a transmission signal can flow into the reception filter 2, or a reception signal can flow into the transmission filter 1 to degrade the characteristics of the counterpart filter. Particularly, if a transmission signal flows from the signal path L1 of the transmission filter 1 into the reception filter 2, the transmission signal causes noise and deteriorated quality of communications, so that it is desirable to eliminate or minimize the transmission signal which flows into the reception filter 2.

To this end, in the present invention, the signal path of at least one of the first SAW element unit and second SAW element unit is extended outside of the center line of the SAW element unit, as mentioned above.

Here, the “outside” refers to a side spaced (far) away from an adjacent SAW element unit. In regard to the first SAW element unit, the outside means a side spaced (far) away from the SAW element unit (i.e., the second SAW element unit) which is to be adjacent to the SAW element unit. In regard to the second SAW element, the outside means a side spaced (far) away from the SAW element unit (i.e., the first SAW element unit) which is to be adjacent to the SAW element unit.

The “center line” refers to a center axis which is orthogonal to a direction in which the first SAW element unit and second SAW element unit are arranged (adjoining direction, i.e., a lateral direction in the example of FIG. 12). More specifically, when the direction in which the first SAW element unit and second SAW element unit are arranged is defined to be the lateral direction, the center line matches the axis of symmetry when the SAW element unit (SAW element formed area in which components of the SAW element (for example, IDT, connection pads, and conductor paths for interconnecting them) are disposed) has a bilaterally symmetric geometry. On the other hand, when the SAW element unit does not have a bilaterally symmetric geometry, the center line means an axis which passes an intermediate point between the innermost (closer to the adjacent SAW element unit) edge and the outermost (furthest away from the adjacent SAW element unit) edge with respect to the lateral direction, and is orthogonal to the lateral direction (in which the first SAW element unit and second SAW element unit are arranged).

Further, the “signal path” refers to a transmission path which couples an input terminal through which a signal is inputted to an output terminal through which the signal is outputted, and is the shortest path through which the signal is transmitted.

By thus routing the signal path of one of the first SAW element unit and second SAW element unit adjacent to each other away from the other, it is possible to prevent coupling between the two SAW element units to accomplish a SAW element which includes a plurality of SAW element units in a reduced size with improved electric characteristics.

Further, in the SAW element of the present invention, the signal path of the other of the first surface acoustic wave element unit and second surface acoustic wave element may be partially extended outside of the center line of the surface acoustic wave element unit. Alternatively, the signal path of each of the first surface acoustic wave element unit and second surface acoustic wave element unit may be extended outside of the center line of each surface acoustic wave element unit. These are intended to satisfactorily prevent the coupling between both SAW element units adjacent to each other.

Further, the branch line may be arranged to interpose between the signal path of the first surface acoustic wave element unit and the signal path of the second surface acoustic wave element unit. When the branch line connected to a ground terminal is interposed between both signal paths, unwanted signals can be passed to the ground to favorably restrain the influence on another adjoining SAW element unit.

A SAW device according to the present invention comprises any of the foregoing SAW elements which is flip-chip mounted on a base substrate, and a lid for hermetically sealing the SAW element. In this SAW device, the lid boy preferably comprises no ground conductor. This is intended to prevent the coupling between the SAW element units through the lid.

In the present invention, the SAW element units are not limited to two, but three or more SAW element units may be included. Each of the series arm resonators and parallel arm resonators can include an interdigital transducer formed on the surface of the piezo-electric substrate, and may comprise a reflector. Further, the SAW device, as referred to in the present invention, is a duplexer, by way of example, but is not so limited, and includes a triplexer, a variety of filter devices, and a variety of other SAW devices which utilize surface acoustic waves and comprise one or more SAW elements (or SAW element units).

According to the present invention, it is possible to reduce coupling which can occur between a plurality of SAW elements, and improve the electric characteristics of a SAW device which comprises a plurality of SAW elements.

### BRIEF DESCRIPTION OF THE DRAWINGS

Other objects, features, and advantages of the present invention will become apparent from the following description of embodiments of the present invention taken in conjunction with the drawings, where the same reference numerals designate the same or corresponding parts.

FIG. 1 is a block diagram illustrating a SAW device (duplexer) according to a first embodiment of the present invention;

FIG. 2 is a circuit diagram illustrating a transmission filter contained in the SAW device according to the first embodiment;

FIG. 3A is a circuit diagram illustrating an example of a reception filter contained in the SAW device according to the first embodiment;

FIG. 3B is a circuit diagram illustrating another example of the reception filter contained in the SAW device according to the first embodiment;

FIG. 4A is a cross-sectional view illustrating an example of the SAW device according to the first embodiment;

FIG. 4B is a cross-sectional view illustrating another example of the SAW device according to the first embodiment;

FIG. 5 is a top plan view schematically illustrating a SAW element contained in the SAW device according to the first embodiment;

FIG. 6 is a graphic representation showing frequency—attenuation characteristics (simulation result) of the duplexer according to the first embodiment in comparison with a conventional SAW element structure;

FIG. 7 is a graphic representation showing isolation characteristics between the transmission and reception filters in the first embodiment;

FIG. 8 is a top plan view schematically illustrating a SAW element contained in a SAW device according to a second embodiment of the present invention;

FIG. 9 is a graphic representation showing frequency—attenuation characteristics (simulation result) of a duplexer according to the second embodiment in comparison with a conventional SAW element structure;

FIG. 10 is a graphic representation showing isolation characteristics between the transmission and reception filters in the second embodiment;

FIG. 11 is a top plan view schematically illustrating another exemplary configuration of a SAW device according to the present invention; and

FIG. 12 is a top plan view schematically illustrating the configuration of a conventional SAW element structure.

### DESCRIPTION OF THE EMBODIMENTS

### First Embodiment

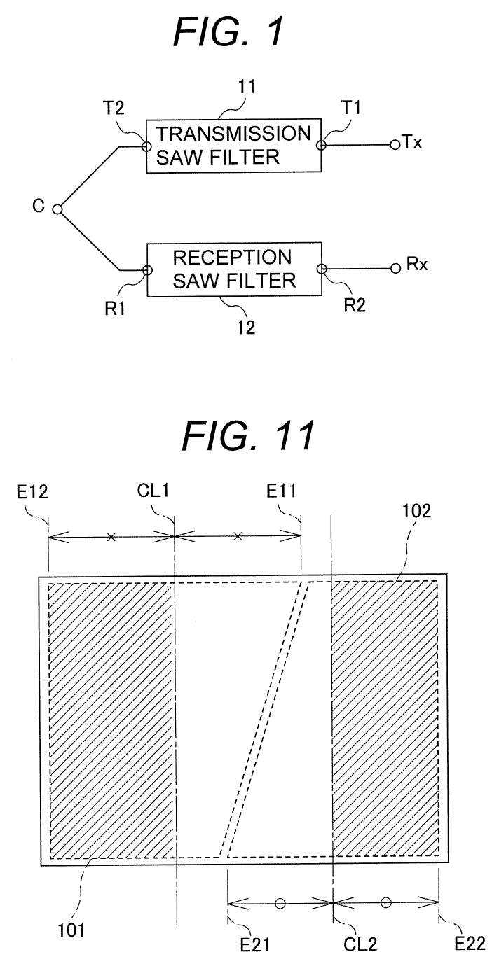

FIG. 1 is a block diagram illustrating a duplexer which is a SAW device according to a first embodiment of the present invention. As illustrated in FIG. 1, this duplexer comprises a transmission filter 11 having a band center frequency f1 and connected to a common terminal C coupled to an antenna; a reception filter 12 having a band center frequency f2 higher than f1 and connected to the common terminal C; a transmission signal terminal Tx through which a transmission signal is inputted; and a reception signal terminal Rx through which a reception signal is outputted.

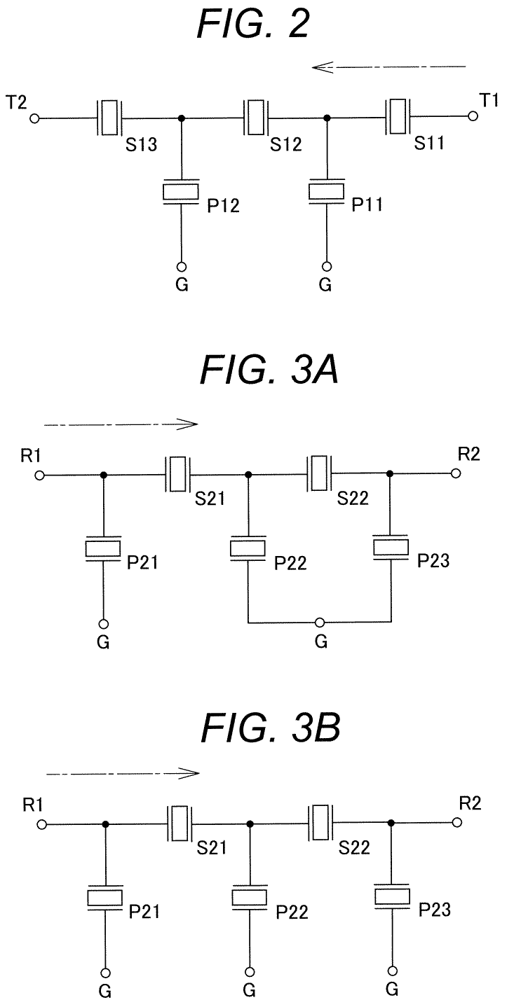

FIGS. 2 and 3A, 3B are circuit diagrams illustrating the configuration of the transmission filter 11 (SAW element unit) and reception filter 12 (SAW element unit), respectively. As illustrated in FIG. 2, the transmission filter 11 comprises three series arm resonators S11, S12, S13 coupled to the transmission signal terminal Tx and connected in series on a transmission path (signal path) between an input terminal T1 through which a transmission signal is inputted and an output terminal T2 through which the transmission signal is outputted; and two parallel arm resonators P11, P12 connected to branch lines, respectively, each of which branches from the signal line to a ground terminal G.

On the other hand, the reception filter 12 comprises two series arm resonators S21, S22 coupled to the common terminal C and connected in series on a transmission path (signal path) between an input terminal R1 through which a reception signal is inputted from the antenna and an output terminal R2 through which the reception signal is outputted; and three parallel arm resonators P21, P22, P23 connected to branch lines, respectively, each of which branches from the signal path to the ground terminal G, as illustrated in FIG. 3A. It should be noted that while the two parallel arm resonators P22, P23 are connected to the common ground terminal G in the exemplary configuration illustrated in FIG. 3A, the parallel arm resonators P22, P23 may be connected to separate ground terminals G, respectively, as illustrated in FIG. 3B.

The resonators S11, S12, S13, S21, S22, P11, P12, P21, P22, P23, which make up the transmission and reception filters 11, 12, are each composed of an interdigital transducer (IDT) formed on a piezo-electric substrate, and reflectors disposed on both sides of the IDT, as will be later described. Also, the configuration of the transmission filter 11 and reception filter 12 is illustrated by way of example, and each of the series arm and parallel arm resonators may vary in the number, connection, arrangement, structure and the like, other than the illustrated examples. Further, in this embodiment, the center frequency f2 on the reception side is higher than the center frequency f1 on the transmission side, but in contrast with this, the center frequency f1 on the transmission side may be higher than the center frequency f2 on the reception side.

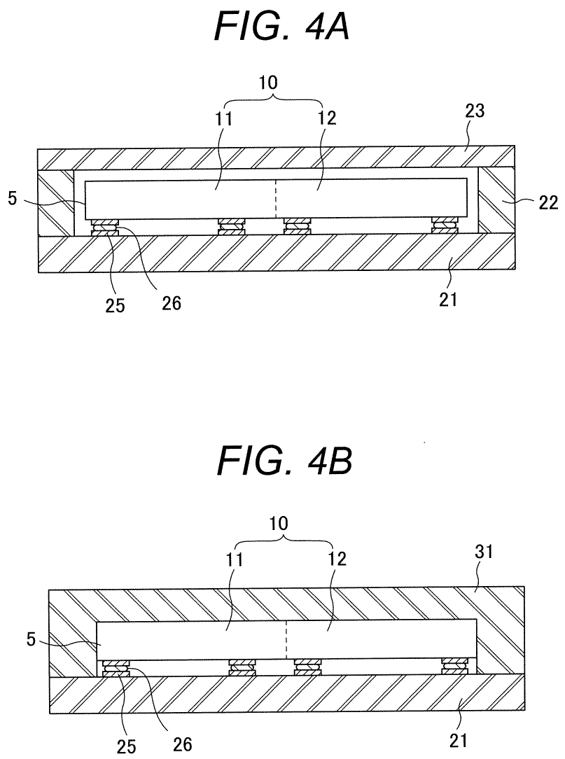

FIGS. 4A and 4B are cross-sectional views illustrating the duplexer according to this embodiment. As illustrated, the duplexer of this embodiment comprises a SAW element 10 mounted on the surface of a base substrate 21; and a lid made up of a frame-shaped substrate 22 surrounding the periphery of the SAW element 10 and a top substrate 23 covering the top surface of the frame-shaped substrate 22 for hermetically sealing the SAW element 10 (see FIG. 4A). The lid (top substrate 23) is not provided with a ground conductor (ground electrode). This is intended to prevent coupling between both filters 11, 12 through the ground conductor. Alternatively, the lid may comprise an integrated (single) sealing material 31 instead of two substrates (the frame-shaped substrate and top substrate), as illustrated in FIG. 4B. Likewise, in the latter structure, the lid 31 is not provided with a ground conductor (ground electrode) for the same reason.

The SAW element 10 has the transmission filter 11 and the reception filter 12 arranged side by side on the surface of a single piezo-electric substrate 5, and is flip-chip mounted in a so-called face down manner while electrically connected to connection pads 25 disposed on the base substrate 21 through metal bumps 26. The base substrate 21 can be, for example, a resin substrate, a ceramics substrate, or a substrate made of a composite material which has an inorganic filler or the like mixed in a resin.

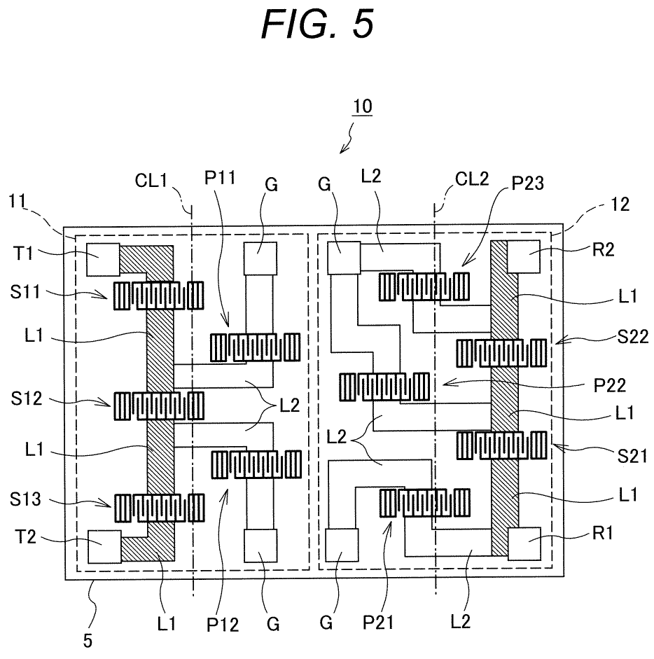

FIG. 5 is a top plan view schematically illustrating the surface of the SAW element 10. As illustrated in FIG. 5, in the SAW element 10 in this embodiment, the transmission filter 11 (first SAW element unit) and the reception filter 12 (second SAW element unit) are formed side by side on the surface of the single piezo-electric substrate 5. The transmission filter 11 comprises three series arm resonators S11, S12, S13 on a signal path L1 which is a transmission path between the input terminal T1 through which a transmission signal is inputted and the output terminal T2 through which the transmission signal is outputted, as described above, and also has parallel arm resonators P11, P12 on branch lines L2 which branch from the signal path L1 to respective ground terminals G.

Here, in this embodiment, when an “inner side” refers to a side closer to the reception filter 12 from a center line CL1 of the transmission filter 11, and an “outer side” refers to a side further from the reception filter 12 (the same terms are applied to the reception filter 12 described below), the signal path L1 of the transmission filter 11 is extended outside of the center line CL1 of the transmission filter 11.

The reception filter 12 in turn comprises two series arm resonators S21, S22 on the signal path L1 which is a transmission path between the input terminal R1 through which a reception signal is inputted from the antenna and the output terminal R2 through which the reception signal is outputted, as described above, and also has parallel arm resonators P21, P22, P23 on branch lines L2, each of which branches from the signal path L1 to a ground terminal G. Then, similar to the transmission filter 11, the signal path L1 of the reception filter 12 is extended outwardly a center line CL2 of the reception filter 12.

Also, the branch lines L2 of the transmission filter 11 and the branch lines L2 of the reception filter 12 are arranged to interpose between the signal path L1 of the reception filter 12 and the signal path L1 of the transmission filter 11.

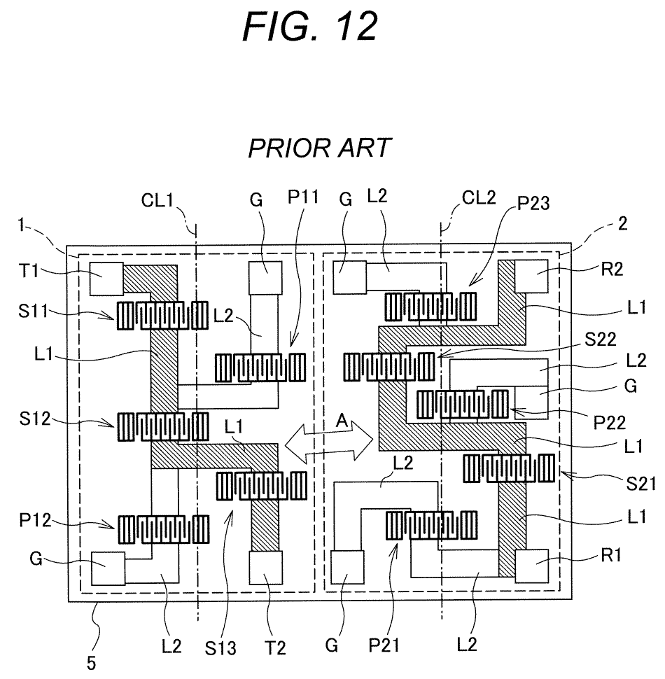

Such routing of the signal paths and branch lines can prevent coupling between the transmission and reception filters 11, 12 to avoid deteriorations in the frequency characteristics of the filters 11, 12 in this embodiment. FIG. 6 is a graphic representation showing the frequency-attenuation characteristics (simulation result) of the duplexer according to the first embodiment in comparison with the conventional SAW element structure (FIG. 12), where reference numeral 11 designates the transmission filter, reference numeral 12 designates the reception filter, a thin line represents the characteristics of the duplexer having the conventional element structure, and a bold line represents the characteristics of the duplexer according to this embodiment.

Table 1 below shows the amount of attenuation caused by the reception filter in a specified frequency range of 830 MHz to 840 MHz in a pass band (attenuation band of the reception filter) of the transmission filter, while Table 2 below shows the amount of attenuation caused by the transmission filter in a specified frequency range of 875 MHz to 885 MHz in a pass band (attenuation range of the transmission filter) of the reception filter.

TABLE 1

| | | | Minimum Amount of |
|---|---|---|---|
| | | | Attenuation |
| | 830 MHz | 840 MHz | (between 830 and 840 MHz) |
| Conventional | 57.9 | 61.0 | 57.9 |
| Structure[dB] | | | |
| First | 65.4 | 68.5 | 64.3 |
| Embodiment[dB] | | | |

TABLE 2

| | | | Minimum Amount of |
|---|---|---|---|
| | | | Attenuation |
| | 875 MHz | 885 MHz | (between 875 and 885 MHz) |
| Conventional | 54.7 | 57.7 | 52.4 |
| Structure[dB] | | | |
| First | 57.3 | 61.0 | 57.3 |
| Embodiment[dB] | | | |

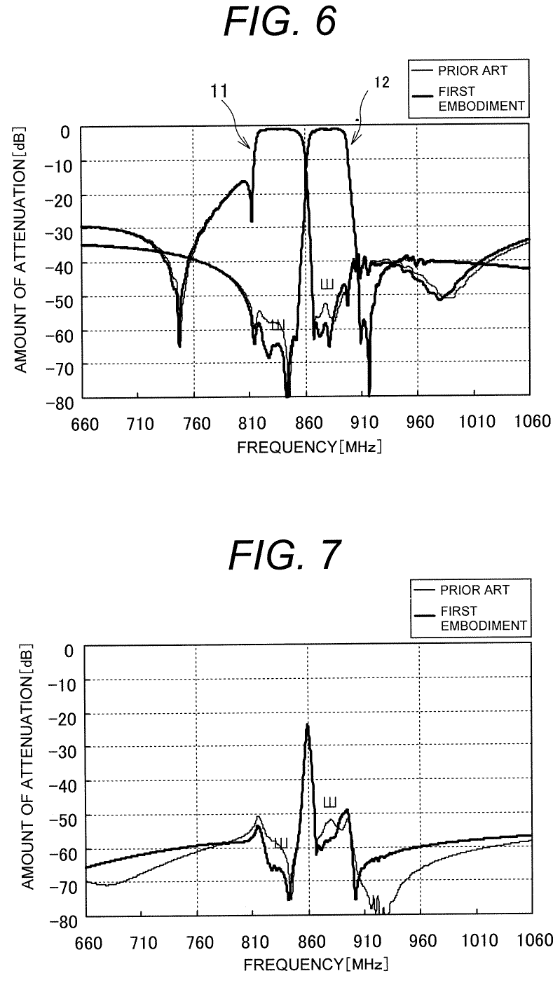

Further, FIG. 7 is a graphic representation showing the isolation characteristics between the transmission and reception filters in this embodiment, where a thin line represents the characteristics of the conventional element structure, and a bold line represents the characteristics of this embodiment, respectively. Table 3 below shows the isolation characteristics (amount of attenuation) between the transmission and reception filters in a specified frequency range of 830 MHz to 840 MHz in the pass band of the transmission filter, while Table 4 below shows the isolation characteristics (amount of attenuation) between the transmission and reception filters in a specified frequency range of 875 MHz to 885 MHz in the pass band of the reception filter.

TABLE 3

| | | | Minimum Amount of |
|---|---|---|---|
| | | | Attenuation |
| | 830 MHz | 840 MHz | (between 830 and 840 MHz) |
| Conventional | 58.1 | 62.7 | 58.1 |
| Structure[dB] | | | |
| First | 65.6 | 70.2 | 65.6 |
| Embodiment[dB] | | | |

TABLE 4

| | | | Minimum Amount of |
|---|---|---|---|
| | | | Attenuation |
| | 875 MHz | 885 MHz | (between 875 and 885 MHz) |
| Conventional | 54.2 | 53.6 | 51.9 |
| Structure[dB] | | | |
| First | 58.7 | 56.6 | 56.6 |
| Embodiment[dB] | | | |

As is apparent from these FIGS. 6, 7 and simulation results shown in Tables 1-4, it can be understood that the element structure of this embodiment can improve the attenuation characteristics in the pass band of the counterpart filter, and the isolation characteristics between the transmission and reception filters, as compared with the conventional element structure.

### Second Embodiment

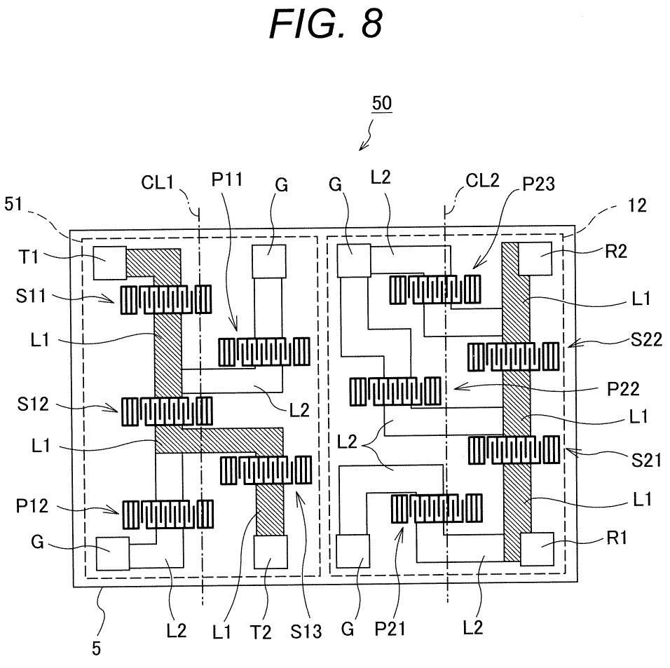

FIG. 8 is a top plan view of a SAW element contained in a SAW device (duplexer) according to a second embodiment of the present invention. Like the first embodiment, this duplexer comprises a SAW element 50 which has a transmission filter 51 and a reception filter 12 formed on a single piezo-electric substrate 5, where a signal path L1 of the reception filter 12 is extended outside of a center line CL2 of the reception filter 12. However, the second embodiment differs from the first embodiment in the structure of the transmission filter 51.

Specifically, the transmission filter 51 has an output terminal T2 connected to the common terminal C and positioned closer to the reception filter, and part of the signal path L1, which connects the output terminal T2 to the input terminal T1 connected to a transmission signal terminal Tx, is routed inside of the center line CL1 of the transmission filter 51 (closer to the reception filter).

However, part of the signal path closer to the input terminal T1 through which a transmission signal is inputted is extended outside of the center line CL1, the signal line L1 of the reception filter 12 is extended outside of the center line CL2, as mentioned above, and branch lines L2 connected to respective ground terminals G are arranged to interpose between the signal paths L1 of the transmission and reception filters 51, 12. Such an arrangement can prevent coupling between both filters 51, 12.

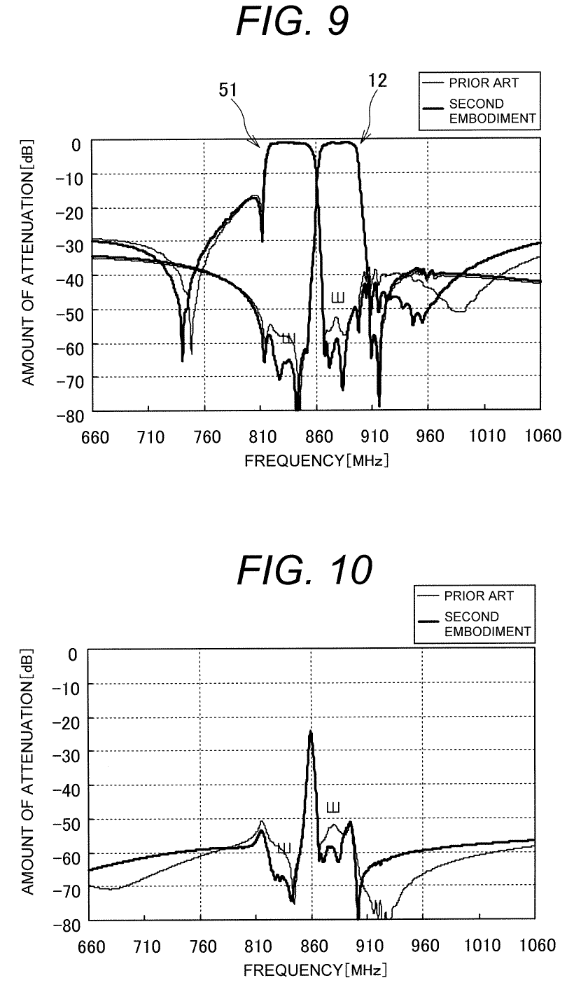

FIGS. 9 and 10 are graphic representations showing the frequency-attenuation characteristics (simulation result) of the duplexer according to the second embodiment in comparison with the conventional SAW element structure (FIG. 12), and the isolation characteristics between the transmission and reception filters, respectively, in a manner similar to FIGS. 6 and 7 mentioned above. Reference numeral 51 designates the transmission filter, and 12 the reception filter. Thin lines represent the characteristics of the conventional element structure, while bold lines represent the characteristics of this embodiment. Also, Table 5 through Table 8 below correspond to Table 1 through Table 4, respectively, where Table 5 shows the amount of attenuation caused by the reception filter; Table 6 the amount of attenuation caused by the transmission filter; and Tables 7 and 8 the isolation characteristics (amount of attenuation) between the transmission and reception filters.

TABLE 5

| | | | Minimum Amount of |
|---|---|---|---|
| | | | Attenuation |
| | 830 MHz | 840 MHz | (between 830 and 840 MHz) |
| Conventional | 57.9 | 61.0 | 57.9 |
| Structure[dB] | | | |
| Second | 66.6 | 69.5 | 65.1 |
| Embodiment[dB] | | | |

TABLE 6

| | | | Minimum Amount of |
|---|---|---|---|
| | | | Attenuation |
| | 875 MHz | 885 MHz | (between 875 and 885 MHz) |
| Conventional | 54.7 | 57.7 | 52.4 |
| Structure[dB] | | | |
| First | 62.7 | 69.2 | 58.8 |
| Embodiment[dB] | | | |

TABLE 7

| | | | Minimum Amount of |
|---|---|---|---|
| | | | Attenuation |
| | 830 MHz | 840 MHz | (between 830 and 840 MHz) |
| Conventional | 58.1 | 62.7 | 58.1 |
| Structure[dB] | | | |
| Second | 66.8 | 71.1 | 66.8 |
| Embodiment[dB] | | | |

TABLE 8

| | | | Minimum Amount of |
|---|---|---|---|
| | | | Attenuation |
| | 875 MHz | 885 MHz | (between 875 and 885 MHz) |
| Conventional | 54.2 | 53.6 | 51.9 |
| Structure[dB] | | | |
| Second | 58.8 | 62.8 | 58.3 |
| Embodiment[dB] | | | |

As is apparent from these FIGS. 9, 10 and simulation results shown in Tables 5-8, it can be understood that the element structure of this embodiment can also improve the attenuation characteristics in the pass band of the counterpart filter, and the isolation characteristics between the transmission and reception filters, as compared with the conventional element structure.

While some embodiments of the present invention have been described above, it will be apparent to those skilled in the art that the present invention is not so limited, but can be modified in various manners without departing from the scope of the invention defined by claims.

For example, the SAW element unit does not necessarily have a symmetric geometry. FIG. 11 illustrates an example of a SAW element unit which has a bilateral asymmetric geometry. In this example, two SAW element units 101, 102 are disposed on a piezo-electric substrate 5, but each SAW element unit 101, 102 is not bilateral symmetric. In this arrangement, in the lateral direction (in which the first SAW element unit 101 and second SAW element unit 102 are arranged), each of axes CL1, CL2 which passes an intermediate point between the innermost (closer to the adjacent SAW element unit) edge (E11 for the first SAW element unit 101, and E21 for the second SAW element unit 102) and the outermost (furthest away from the adjacent SAW element unit) edge (E12 for the first SAW element unit 101, and E22 for the second SAW element unit 102) and is orthogonal to the lateral direction (in which the first SAW element unit 101 and second SAW element unit 102 are arranged) is defined as the center line of each SAW element unit, and one or both of the signal paths may be extended outside of these axes (hatched areas).

It should be noted that when a signal path is extended outside of the center line in accordance with the present invention, the entirety of the signal path need not be extended completely outside of the center line, but a substantial entirety of the signal path may be extended outside of the center line (part may be positioned inside the center line). This is because similar (substantially equivalent) advantages can be provided as long as the majority of the signal path is extended in a region outside of the center line.

What is claimed is:

1. A surface acoustic wave element comprising:
a first surface acoustic wave element unit formed on a surface of a piezo-electric substrate; and
a second surface acoustic wave element unit formed on the surface of said piezo-electric substrate adjacent to said first surface acoustic wave element unit,
wherein each of said first surface acoustic wave element unit and said second surface acoustic wave element unit includes:
an input terminal for inputting a signal therethrough;
an output terminal for outputting a signal therethrough;
a ground terminal connected to a ground;
a signal path for coupling said input terminal and said output terminal;
one or more series arm resonators connected in series on said signal path;
a branch line branched from said signal path to said ground terminal; and
one or more parallel arm resonators connected on said branch line,
wherein said signal path of at least one of said first surface acoustic wave element unit and said second surface acoustic wave element unit is extended outside of a center line of said surface acoustic wave element unit.

2. A surface acoustic wave element according to claim 1, wherein:
said signal path of the other of said first surface acoustic wave element unit and said second surface acoustic wave element unit is partially extended outside of the center line of said surface acoustic wave element unit.

3. A surface acoustic wave element according to claim 1, wherein:
said signal path of each of said first surface acoustic wave element unit and said second surface acoustic wave element unit is extended outside of the center line of each surface acoustic wave element unit.

4. A surface acoustic wave element according to claim 1, wherein:
said branch line is arranged to interpose between the signal path of said first surface acoustic wave element unit and the signal path of said second surface acoustic wave element unit.

5. A surface acoustic wave element according to claim 2, wherein:
said branch line is arranged to interpose between the signal path of said first surface acoustic wave element unit and the signal path of said second surface acoustic wave element unit.

6. A surface acoustic wave element according to claim 3, wherein:
said branch line is arranged to interpose between the signal path of said first surface acoustic wave element unit and the signal path of said second surface acoustic wave element unit.

7. A surface acoustic wave device comprising:
a base substrate on which a surface acoustic wave element can be mounted;
a surface acoustic wave element flip-chip mounted on said based substrate; and
a lid for hermetically sealing said surface acoustic wave element,
wherein said surface acoustic wave element comprises:
a first surface acoustic wave element unit formed on a surface of a piezo-electric substrate; and
a second surface acoustic wave element unit formed on the surface of said piezo-electric substrate adjacent to said first surface acoustic wave element unit,
each of said first surface acoustic wave element unit and said second surface acoustic wave element unit includes:
an input terminal for inputting a signal therethrough;
an output terminal for outputting a signal therethrough;
a ground terminal connected to a ground;
a signal path for coupling said input terminal and said output terminal;
one or more series arm resonators connected in series on said signal path;
a branch line branched from said signal path to said ground terminal; and
one or more parallel arm resonators connected on said branch line, and
said signal path of at least one of said first surface acoustic wave element unit and said second surface acoustic wave element unit is extended outside of a center line of said surface acoustic wave element unit.

8. A surface acoustic wave device according to claim 7, wherein:
said signal path of the other of said first surface acoustic wave element unit and said second surface acoustic wave element unit is partially extended outside of the center line of said surface acoustic wave element unit.

9. A surface acoustic wave device according to claim 7, wherein:
said signal path of each of said first surface acoustic wave element unit and said second surface acoustic wave element unit is extended outside of the center line of each surface acoustic wave element unit.

10. A surface acoustic wave device according to claim 7, wherein:
said branch line is arranged to interpose between the signal path of said first surface acoustic wave element unit and the signal path of said second surface acoustic wave element unit.

11. A surface acoustic wave device according to claim 8, wherein:
said branch line is arranged to interpose between the signal path of said first surface acoustic wave element unit and the signal path of said second surface acoustic wave element unit.

12. A surface acoustic wave device according to claim 9, wherein:
said branch line is arranged to interpose between the signal path of said first surface acoustic wave element unit and the signal path of said second surface acoustic wave element unit.

13. A surface acoustic wave device according to claim 7, wherein said lid does not comprise a ground conductor.

14. A surface acoustic wave device according to claim 8, wherein said lid does not comprise a ground conductor.

15. A surface acoustic wave device according to claim 9, wherein said lid does not comprise a ground conductor.

16. A surface acoustic wave device according to claim 10, wherein said lid does not comprise a ground conductor.

17. A surface acoustic wave device according to claim 11, wherein said lid does not comprise a ground conductor.

18. A surface acoustic wave device according to claim 12, wherein said lid does not comprise a ground conductor.
